(19) United States
(12) Patent Application Publication
(10) Pub. No.: US 2024/0395687 A1
(43) Pub. Date: Nov. 28, 2024

(54) ELECTRONIC PACKAGE AND CARRIER STRUCTURE THEREOF

(71) Applicant: SILICONWARE PRECISION INDUSTRIES CO., LTD., Taichung City (TW)

(72) Inventors: Ching-Chih LIN, Taichung City (TW); Wen-Hsin WANG, Taichung City (TW); Shin-Yu WANG, Taichung City (TW); Hsiu-Fang CHIEN, Taichung City (TW)

(21) Appl. No.: 18/366,009

(22) Filed: Aug. 7, 2023

(30) Foreign Application Priority Data
May 23, 2023 (TW) 112119156

(51) Int. Cl. H01L 23/498

(52) U.S. Cl. CPC H01L 23/49838; H01L 24/16; H01L 24/32; H01L 24/73; H01L 2224/16227; H01L 2224/32225; H01L 2224/73204

(57) ABSTRACT

An electronic package and a carrier structure thereof are provided, in which the carrier structure is used for disposing a semiconductor chip and defined with a die placement area and a peripheral area adjacent to the die placement area on a surface thereof, and a winding shape of conductive traces arranged at a boundary between the die placement area and the peripheral area is a continuous bending shape with notches to facilitate dispersion of thermal stress, thereby preventing the problem of breakage from occurring to line segments of the conductive traces.

### BACKGROUND

### 1. Technical Field

The present disclosure relates to a semiconductor packaging technology, and more particularly, to an electronic package that improves reliability and a carrier structure thereof.

### 2. Description of Related Art

With the vigorous development of the electronic industry, electronic products are gradually developing toward the trend of multi-function and high performance. Recently, there are many technologies used in the field of chip packaging, such as chip scale package (CSP), direct chip attached (DCA), flip-chip package module, etc.

In the conventional flip-chip package process, as shown in FIG. 1A, a semiconductor chip 11 is bonded onto a circuit layer 100 of a die placement area A of a package substrate 10 by solder bumps 12 with electrode pads 110 of the semiconductor chip 11, so that an outline of the semiconductor chip 11 corresponds to a boundary of the die placement area A. Afterward, an underfill 13 is formed between the semiconductor chip 11 and the package substrate 10 to cover the solder bumps 12, and the underfill 13 is spread to a peripheral area B around the die placement area A, so that the manufacturing process of a flip-chip semiconductor package 1 is completed.

However, in the conventional semiconductor package 1, there is a huge difference in coefficient of thermal expansion (CTE mismatch) between the semiconductor chip 11 and the package substrate 10, so that the thermal stress generated by the high temperature environment formed in the subsequent process of a reliability test or a reflow operation of the semiconductor package 1 will not be able to disperse, which results in a die corner stress formed at each corner of the die placement area A due to the stress concentration in the boundary between the die placement area A and the peripheral area B of the package substrate 10 (e.g., around a boundary line 10a shown in FIG. 1B), and the strong die corner stress will stretch a conductive trace 101 of the circuit layer 100, so that the conductive trace 101 at the boundary between the die placement area A and the peripheral area B is broken (such as a crack K shown in FIG. 1A and FIG. 1B), resulting in poor reliability of the semiconductor package 1.

Therefore, there is a need for a solution that addresses the aforementioned shortcomings in the prior art.

### SUMMARY

In view of the aforementioned shortcomings of the prior art, the present disclosure provides a carrier structure, comprising: a dielectric body with a surface defined with at least one die placement area and a peripheral area adjacent to the die placement area; and a circuit layer bonded to the dielectric body and comprising a plurality of conductive traces, wherein a winding shape of the conductive traces arranged at a boundary between the die placement area and the peripheral area is a continuous bending shape with notches.

The present disclosure also provides an electronic package, comprising: the aforementioned carrier structure; and an electronic element disposed on the carrier structure and electrically connected to the circuit layer.

In the aforementioned electronic package and carrier structure, the winding shape of the conductive traces is a serpentine shape.

In the aforementioned electronic package and carrier structure, the winding shape of the conductive traces is a tombstone shape.

In the aforementioned electronic package and carrier structure, the winding shape of the conductive traces is a zigzag shape.

In the aforementioned electronic package and carrier structure, the winding shape of the conductive traces is a curved shape or a wavy shape.

As can be understood from the above, in the electronic package and the carrier structure thereof according to the present disclosure, the carrier structure is arranged with the continuous-bending-shaped conductive traces having notches around the boundary between the die placement area and the peripheral area of the carrier structure, so that when the electronic package is subject to reliability test or reflow operations, etc., the thermal stress generated at the boundary between the die placement area and the peripheral area in a high temperature environment can be dispersed. Therefore, compared with the prior art, the present disclosure can avoid the problem of line segment breakage of conductive traces at the boundary between the die placement area and the peripheral area of the carrier structure (in particular at corners), so as to improve the reliability of the electronic package.

### BRIEF DESCRIPTION OF THE DRAWINGS

FIG. 1A is a schematic cross-sectional view of a conventional semiconductor package.

FIG. 1B is a schematic partial top view of a package substrate of the conventional semiconductor package.

FIG. 2A is a schematic cross-sectional view of an electronic package of the present disclosure.

FIG. 2B is a schematic partial top view of a carrier structure of the present disclosure.

FIG. 3A, FIG. 3B, FIG. 3C and FIG. 3D are schematic partial enlarged top views of different embodiments at a circle C in FIG. 2B.

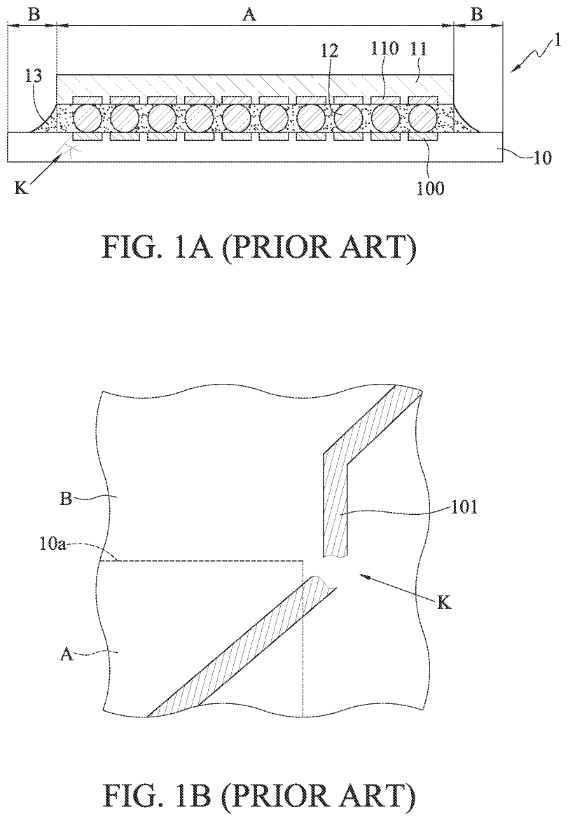

### DETAILED DESCRIPTION

Implementations of the present disclosure are described below by embodiments. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes or adjustments to the structures, ratios, or sizes are construed as falling within the scope covered by the technical contents disclosed herein. Meanwhile, terms such as “on,” “above,” “a,” “one,” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

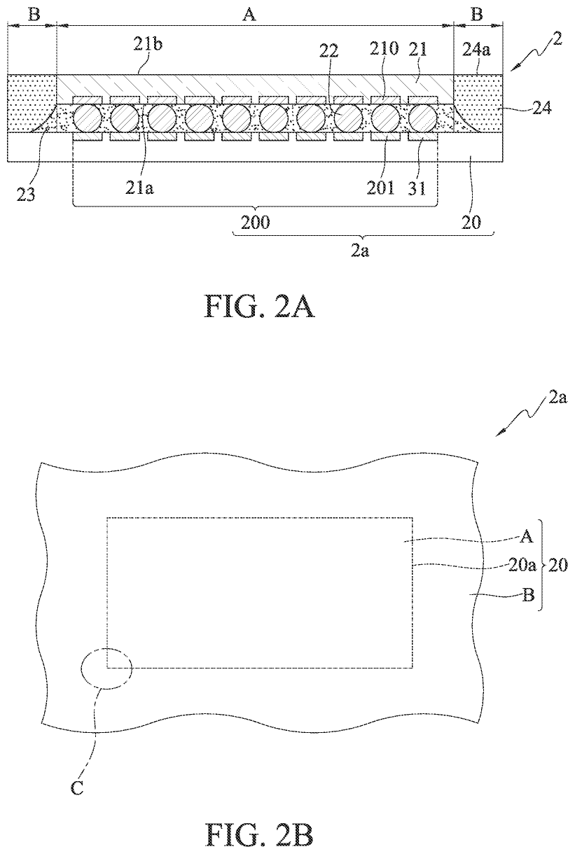

FIG. 2A is a schematic cross-sectional view of an electronic package 2 of the present disclosure, and FIG. 2B is a schematic partial top view of a carrier structure 2a of the present disclosure.

As shown in FIG. 2A, the electronic package 2 comprises: the carrier structure 2a and at least one electronic element 21 bonded to the carrier structure 2a.

The carrier structure 2a has a dielectric body 20 of which a surface is defined with at least one die placement area A and a peripheral area B adjacent to the die placement area A, as shown in FIG. 2B.

In an embodiment, the carrier structure 2a can be a package substrate with a core layer or a coreless package substrate, of which in the dielectric body 20 is formed with at least one circuit layer 200, such as a redistribution layer (RDL), wherein the single circuit layer 200 comprises a plurality of conductive traces 201. For example, the material forming the circuit layer 200 is copper, and the material of the dielectric body 20 is polybenzoxazole (PBO), polyimide (PI), prepreg (PP), or others. It should be understood that in other embodiments, the carrier structure 2a may also be a semiconductor substrate having a plurality of conductive through-silicon vias (TSVs), such as a through-silicon interposer (TSI).

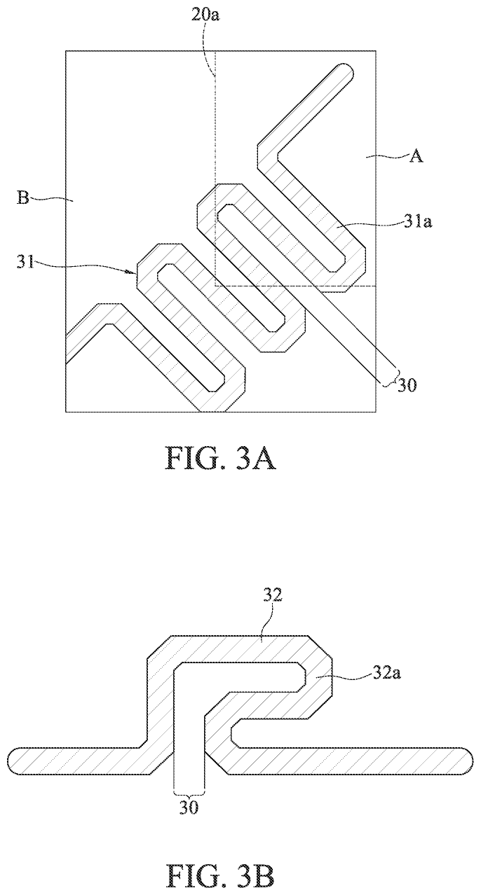

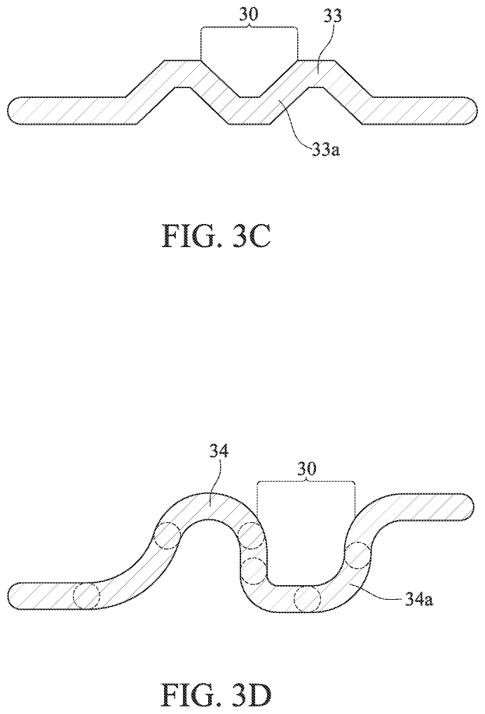

Furthermore, a conductive trace 31 arranged at the boundary between the die placement area A and the peripheral area B (i.e., around a boundary line 20a) has a plurality of line segments 31a, as shown by the corner of the die placement area A in FIG. 3A, the winding shape of the conductive trace 31 is a serpentine shape. Alternatively, as shown by line segments 32a in FIG. 3B, the winding shape of a conductive trace 32 is similar to the shape of an English letter R. Alternatively, as shown by line segments 33a in FIG. 3C, the winding shape of a conductive trace 33 is a zigzag shape. Alternatively, the winding shape of a conductive trace 34 formed by a plurality of line segments 34a shown in FIG. 3D has a curved shape or a wavy shape. It should be understood that the winding shapes of the conductive traces 31, 32, 33, 34 arranged at the boundary between the die placement area A and the peripheral area B (i.e., around the boundary line 20a) can be designed according to requirements, as long as a continuous bending shape with notches 30 is presented.

Therefore, the carrier structure 2a of the present disclosure is arranged with the conductive traces 31, 32, 33, 34 being a continuous bending shape with the notches 30 around the boundary between the die placement area A and the peripheral area B, so that when the electronic package 2 is subject to reliability test or reflow operations, etc., the thermal stress generated at the boundary between the die placement area A and the peripheral area B (i.e., around the boundary line 20a) in a high temperature environment can be dispersed. Therefore, compared with the prior art, the continuous-bending-shaped conductive traces 31, 32, 33, 34 of the present disclosure can suppress the die corner stress generated at the boundary (in particular at the corners) between the die placement area A and the peripheral area B of the carrier structure 2a from stretching the line segments 31a, 32a, 33a, 34a of the conductive traces 31, 32, 33, 34, so that the line segments 31a, 32a, 33a, 34a of the conductive traces 31, 32, 33, 34 will not be broken, thereby effectively improving the reliability of the electronic package 2.

Moreover, even if the die corner stress stretches the line segments 31a, 32a, 33a, 34a of the conductive traces 31, 32, 33, 34, the stretching effect is not enough to break the line segments 31a, 32a, 33a, 34a of the conductive traces 31, 32, 33, 34, so that the reliability of the electronic package 2 can be ensured to meet the requirements.

The electronic element 21 is an active element, a passive element, a package module, or a combination thereof, and the electronic element 21 is arranged on the circuit layer 200 of the die placement area A of the carrier structure 2a, wherein the active element may be a semiconductor chip, and the passive element may be a resistor, a capacitor, or an inductor.

In an embodiment, the electronic element 21 is a semiconductor chip and has an active surface 21a and an inactive surface 21b opposing the active surface 21a, and the active surface 21a has a plurality of electrode pads 210 thereon, and the electrode pads 210 of the electronic element 21 is electrically connected to the circuit layer 200 of the die placement area A of the carrier structure 2a via conductive bumps 22 in a flip-chip manner, and an encapsulation layer 23 is formed between the active surface 21a and the carrier structure 2a, so that the encapsulation layer 23 covers the conductive bumps 22. For example, the conductive bumps 22 are metal pillars (such as copper pillars), solder material, or a combination thereof, and the encapsulation layer 23 is an underfill or a non-conductive film (NCF), but not limited to the above.

Furthermore, a packaging layer 24 covering the electronic element 21 can be formed on the carrier structure 2a according to requirements, and the packaging layer 24 can be made of an insulating material, such as polyimide (PI), dry film, epoxy resin, molding compound, or other suitable materials. For example, the packaging layer 24 is formed on the carrier structure 2a in a manner of lamination or molding.

In addition, part of the material of the packaging layer 24 can be removed by a flattening process or a thinning process, so that the inactive surface 21b of the electronic element 21 is coplanar with a surface 24a of the packaging layer 24, such that the inactive surface 21b of the electronic element 21 is exposed from the packaging layer 24.

In view of the above, in the electronic package and the carrier structure thereof according to the present disclosure, the carrier structure is arranged with the continuous-bending-shaped conductive traces around the boundary between the die placement area and the peripheral area of the carrier structure, so that when the electronic package is subject to reliability test or reflow operations, etc., the thermal stress generated at the boundary between the die placement area and the peripheral area in a high temperature environment can be dispersed. Therefore, the present disclosure can avoid the problem of line segment breakage of conductive traces at the boundary between the die placement area and the peripheral area of the carrier structure (in particular at corners), so as to improve the reliability of the electronic package.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A carrier structure, comprising:
a dielectric body with a surface defined with at least one die placement area and a peripheral area adjacent to the die placement area; and
a circuit layer bonded to the dielectric body and comprising a plurality of conductive traces, wherein a winding shape of the conductive traces arranged at a boundary between the die placement area and the peripheral area is a continuous bending shape with notches.

2. The carrier structure of claim 1, wherein the winding shape of the conductive traces is a serpentine shape.

3. The carrier structure of claim 1, wherein the winding shape of the conductive traces is a tombstone shape.

4. The carrier structure of claim 1, wherein the winding shape of the conductive traces is a zigzag shape.

5. The carrier structure of claim 1, wherein the winding shape of the conductive traces is a curved shape or a wavy shape.

6. An electronic package, comprising:
the carrier structure of claim 1; and
an electronic element disposed on the carrier structure and electrically connected to the circuit layer.

7. The electronic package of claim 6, wherein the winding shape of the conductive traces is a serpentine shape.

8. The electronic package of claim 6, wherein the winding shape of the conductive traces is a tombstone shape.

9. The electronic package of claim 6, wherein the winding shape of the conductive traces is a zigzag shape.

10. The electronic package of claim 6, wherein the winding shape of the conductive traces is a curved shape or a wavy shape.
